(19) United States
(12) Patent Application Publication
(10) Pub. No.: US 2024/0194623 A1
(43) Pub. Date: Jun. 13, 2024

(54) METALLIZED SEMICONDUCTOR DIE AND MANUFACTURING METHOD

(71) Applicant: TDK ELECTRONICS AG, München (DE)

(72) Inventors: Mehrdad Shayganpoor, Raaba (AT); Guenter Aflenzer, Premstätten (AT); Davor Tomassevic, Bunjani (HR); Thomas Feichtinger, Graz (AT)

(21) Appl. No.: 18/554,923

(22) PCT Filed: Mar. 8, 2022
(86) PCT No.: PCT/EP2022/055910

§ 371 Date: Oct. 11, 2023

(30) Foreign Application Priority Data
Apr. 22, 2021 (DE) 10 2021 110 276.6

(51) Int. Cl. H01L 23/00; H01L 21/56; H01L 21/784; H01L 23/31

(52) U.S. Cl. CPC H01L 24/05; H01L 21/561; H01L 23/3171; H01L 24/02; H01L 24/03; H01L 24/06; H01L 24/95; H01L 21/784; H01L 2224/0231; H01L 2224/02331; H01L 2224/02371; H01L 2224/02375; H01L 2224/02381; H01L 2224/0239; H01L 2224/03002; H01L 2224/03422; H01L 2224/05008; H01L 2224/05082; H01L 2224/05139; H01L 2224/05147; H01L 2224/05155; H01L 2224/05164; H01L 2224/0529; H01L 2224/05339; H01L 2224/05347; H01L 2224/05548; H01L 2224/05583; H01L 2224/05611; H01L 2224/05644; H01L 2224/06181; H01L 2224/95001; H01L 2924/01028; H01L 2924/01029; H01L 2924/01046; H01L 2924/01047; H01L 2924/0105; H01L 2924/01079; H01L 2924/0132; H01L 2924/10253; H01L 2924/1203

(57) ABSTRACT

A semiconductor die and a method for manufacturing a semiconductor die are disclosed. In an embodiment a semiconductor die includes a base body having a semiconductor material and a surface with two contact areas having contact pads at which the semiconductor die is electrically contactable and two metal caps arranged directly at the contact pads.

### CROSS-REFERENCE TO RELATED APPLICATIONS

This patent application is a national phase filing under section 371 of PCT/EP2022/055910, filed Mar. 8, 2022, which claims the priority of German patent application 102021110276.6, filed Apr. 22, 2021, each of which is incorporated herein by reference in its entirety.

### TECHNICAL FIELD

The present invention relates to a metallized semiconductor die and to a method of manufacturing and metallizing a semiconductor die.

### BACKGROUND

In consumer electronic devices ESD (electrostatic discharge) protection becomes essential to ensure robustness in harsh transient environments. Transient voltage suppression (TVS) diodes manufactured as surface mounted devices (SMD) or chip size packages (CSP) devices span a broad range of protecting electronic devices at system level. To achieve the miniaturising target of future devices, CSP devices manufactured by wafer level chip scale packaging (WLCSP) technology has been increasingly used for the miniaturisation of semiconductor components.

State of the art semiconductor dies are manufactured with different passivation layers and contacting areas in several steps.

Patent DE 10 2005 004 160 B4 discloses a semiconductor element manufactured by WLCSP technology comprising a passivation layer, electrical contact areas and contact pads applied to the electrical contact areas.

Patent application US 2014/26488 A1 describesmanufacturing of a semiconductor die from a wafer with a passivation step after singulating the dies. Two contact pads are formed on a surface of each semiconductor die, and the semiconductor dies are subsequently singulated from the wafer. A passivation layer is applied to the singulated dies, but does not cover the contact pads.

Patent application US 2012/104414 A1 describes another method of fabricating a semiconductor die from a wafer. Two contact pads are applied to one surface of each semiconductor die and a passivation layer is formed on the opposite surface of the wafer. The dies are then separated from the wafer.

Patent application WO 2018/151405 A1 describes a chip package, wherein a semiconductor chip is embedded in an insulating body.

Patent application DE 10 2011 056 515 A1 discloses an electrical SMD component based on a passivated ceramic or semi-conductor body with inner electrodes, to which external contact pads and metal caps are applied.

Patent application JP 2012-4480 A relates to a process for applying external metallization on multilayer ceramic bodies and subsequent curing of the metallization layers. In particular, metallic pastes are applied to side surfaces of the ceramic body by screen printing and then dried for curing and sintered at elevated temperatures.

Patent application JP 2002-184645 A relates to a production process of terminal electrodes, wherein the end portion of a chip is dipped in a conductor paste of silver to form a coating film, which is dried and then sintered at 600° C. or higher. A nickel or a tin coating is then applied.

### SUMMARY

Embodiments provide an improved semiconductor die and a method for manufacturing a semiconductor die.

The semiconductor die comprises a base body comprising a semiconductor material, a surface with two contact areas provided with contact pads at which the die can be contacted electrically and two metal caps applied directly to the contact pads.

The base body of the die comprises a semiconductor material. The base body can mainly consist of the semiconductor material. The semiconductor material may comprise a silicon

(Si) material. The die based on a semiconductor material can be used as a TVS diode for ESD protection applications. In further embodiments the die may be used as a micro-electro-mechanical system (MEMS) device for different applications. Alternatively or additionally, the die may comprise a mineral material. The mineral material may comprise a ceramic. The die may be used as capacitor, varistor or thermistor.

There are several advantages of applying the metal caps to the contact pads.

First, the dies can be externally electrically contacted by the metal caps which have a significant larger outer surface than the contact pads. Due to a passivation layer, the occurrence of electrical current between the metal caps and 25 regions of the dies other than the contact pads can be prevented.

Further, the dimensions of the contact pads can even be reduced. Smaller contact pads allow to increase the distance between the contact pads. An increased distance between the contact pads reduces unwanted effects such as leakage current or parasitic capacitance.

Furthermore, because of the large outer surface area of the metal caps, the assembly process of the dies on other devices such as PCBs (printed circuit boards) is simplified. The described metal caps show preferably excellent solderability properties.

The additional metallization of the dies provided by the metal caps further enhances their stability and in particular the bending strength and shear strength of the whole dies.

To summarize, by applying metal caps to the electrical contact regions of dies, e.g. TVS diodes, the dies' electrical properties can be improved, the assembly process of the dies on a PCB is simplified and a stable and safe electric contact between the dies and external devices can be achieved.

The die may have a cuboid shape with six rectangular sides.

Preferably, the base body is monolithic and comprises no further components or structural elements.

In an embodiment, the semiconductor die further comprises two interlayers connecting the contact areas with the contact pads.

The contact areas, the optional interlayers and the contact pads each comprise electrically conductive materials. Preferably, they comprise conductive metals or mixtures of metals. The composition of the material of each of the three described structural elements differs from each other. For example, the contact area comprises a material selected from aluminum or copper and the contact pad comprises a material selected from copper, nickel or gold.

While the contact area is configured to contact the semiconductor material of the base body electrically, the contact pad is configured to contact an external electrical contact. The interlayer is configured to connect the contact area and the contact pad electrically and mechanically. By the interlayer the connection between the contact pad and the contact area can be optimized.

Furthermore a method of manufacturing and metallizing a semiconductor die is disclosed which comprises several steps. The following numeration of the steps does not define the order in which the steps are performed. The steps may be performed in the order of the numeration.

All features of the semiconductor die described above can be applied to a semiconductor die manufactured by the following method. On the other hand, all features of a semiconductor die manufactured by the following method can also be applied to the semiconductor die disclosed above.

In a first step a die is provided comprising a base body comprising a semiconductor material and a surface with two contact areas for electrically contacting the die. The die may be configured to work as a diode, for example as a TVS diode.

The contact areas are provided with contact pads, applied to the contact areas. The contact pads serve as an electrical contact element between an external contact and the contact area or an optional interlayer of the die. The external contact is for example and electrical contact on a printed circuit board (PCB).

In a second step a passivation layer for electrical passivation is applied to the surface of the die. The passivation layer may cover the whole surface of the die, except non-passivated areas. Thereby areas free of passivation, said non-passivated areas, are provided allowing external access to each contact pad. The passivation layer electrically isolates the surface of the die. Furthermore, the passivation layer protects the die against environmental impacts or physical and chemical reactions. Preferably, the whole surface of the die except the contact pads or at least parts of each contact pad is passivated.

In a preferred embodiment the passivation layer may be applied by an ALD (atomic layer deposition) process or by a CVD (chemical vapor deposition) process. Areas that are not to be passivated (non-passivated areas) can be covered with a protection tape during the passivation process.

In a third step parts of the surface of the die are covered with metal caps by a metallization process. The metal caps contact the contact pad directly.

In a preferred embodiment, the steps are performed in the stated order.

In an embodiment, a frontside of the die comprises at least a first contact area arranged near a first side of the die and a second contact area arranged near a second side of the die.

In a preferred embodiment, the second side is arranged opposite to the first side, wherein the first side and the second side are perpendicular to the frontside.

The die may have a cuboid shape with six rectangular sides.

The described shape is advantageous for assembling dies, for example on a PCB.

In an embodiment, the step of metallizing may comprise several further steps.

In a first further step, the die is loaded to a first metallization tape on a first side. The metallization tape may be a polymer tape with an adhesive layer. The adhesive layer may have thermo-releasable properties. This means that the tape can be released from the die by heating to a defined temperature. The metallization tape carries the die and protects the first side during a first metallization step.

In a following step, a contiguous area of the die not covered by the first metallization tape, including at least one contact pad, is metalized.

Preferably, an area on the frontside of the die is metallized. Additionally, the second side and sections of the other sides adjacent to the second side may be metallized.

Thereafter, the first side is released from the first metallization tape.

In an embodiment, the step of metallizing comprises the steps of loading the die on a first side to a first metallization tape, metallizing a contiguous area of the die not covered by the first metallization tape including at least one contact pad, loading the die on a second side to a second metallization tape and metallizing a contiguous area of the die not covered by the second metallization tape including at least one contact pad.

In a preferred embodiment, the step of metallizing may comprise the steps of loading the first side of the die to the first metallization tape and metallizing a contiguous area on the frontside and the second side of the die and loading the second side to a second metallization tape and metallizing a contiguous area on the frontside and the first side of the die. Herein, said contiguous area comprises a second contact pad on the frontside. The second contact pad contacts a second contact area of the die.

By providing two contact pads an electric circuit can be designed. In further embodiments the diode comprises several contact areas with contact pads.

The contact pads comprise an electrically conductive metal like copper, nickel or gold.

In an embodiment, the method comprises the additional steps of hardening a metal cap on the second side of the die after the first metallizing step and hardening a metal cap on the first side of the die after a second metallizing step.

The hardening steps may be performed by thermo treating, for example by holding the die at a specific temperature for a specific time period.

In an embodiment, the method comprises the additional steps of releasing the first side from the first metallization tape after a first metallizing step and releasing the second side from the second metallization tape, after a second metallizing step.

The first metallization tape is released before the second metallization step. Therefore the first metallization tape can be used as the second metallization tape. Both metallization tapes may comprise a thermo-releasable adhesive layer and may therefore be released by heating. The releasing steps may be performed after the above described hardening steps.

In a preferred embodiment, the contact pads are fully covered by the metal caps after metallizing. Thus, the die is externally contacted via the metal caps in a reliable and safe manner. More precisely, the metal caps are configured to connect the die electrically to an external electrical contact.

In an embodiment, the metal caps are directly applied to the passivation layer. There are no further layers between the contact pad and the passivation layer. The direct application of the contact pads improves their attachment to the die.

In an embodiment, the metal cap is contiguously applied to an end face perpendicular to the frontside and four sides adjacent to the end face of the die.

Since the metal cap is applied to several sides of each die, the TVS diodes can further be assembled without orientation requirements.

In an embodiment, the metal caps are applied by a dipping process. The dipping process allows the metallization of the die in a simple and comparable cheap way.

In an embodiment, the metal caps comprise two or three different layers applied by two or three metallization steps, for example by two or three dipping steps. The metallization layers are preferably stacked one over another.

The first layer applied directly to the contact pad and the surrounding passivation layer may comprise a soft metallization mixture comprising Ag or Cu and a polymer. The soft properties of the material of the first layer reduce or prevent mechanical or thermo-mechanical stress effects like the occurrence of cracks at the interface between die and passivation layer or passivation layer and metal cap.

The second layer applied directly on the first layer comprises a good electrical conductor like Cu or Ni or an Ag—Pd alloy and protects the first layer against environmental impacts and chemical or physical reactions.

The third layer applied directly on the second layer is configured as an oxidation protection layer and comprises an appropriate metal like Au or Sn.

All three layers are electrically conductive.

In an embodiment, the metal caps comprise metals or a mixture of metals which is different from that of the contact pads, which comprise for example Ni and/or Cu and/or Au. In a preferred embodiment, the first layer of the metal cap comprises another metal than the contact pad.

In an embodiment, the passivation layer is applied by an atomic layer deposition process. Preferably, the atomic layer deposition process is performed at a temperature lower than 80° C., more preferably at room temperature.

In so called CVD (chemical vapor deposition) processes, reactive species react in a gas phase under a controlled atmosphere and elevated temperature to deposit a layer. The CVD process is usually performed at relatively high temperature which may potentially introduce impurities from the gas atmosphere into the layer of deposited material. Technically, such a high required deposition temperature for CVD processes limits the choice and hence the functionality of materials including the tape that are involved in the process.

The ALD process, on the other hand, has the main advantage of being capable of depositing layers in a low temperature regime with high uniformity and quality. In general, ALD as a variant of the CVD process, involves the deposition of a monolayer on any target substrate. Multiple monolayers can be deposited by systematically repeating cycles including dosage of gaseous precursor into a deposition chamber, reacting same with the surface of the target and flushing the chamber with an inert gas to purge out the not chemisorbed precursors. In the present method, the ALD process is preferred considering the introduced tape and the specific required passivation material due to the demanded crucial properties of the passivation layer (electrical, mechanicaletc.).

In an embodiment, the dies are manufactured by a wafer level chip scale packaging process.

In a wafer level chip scale packaging process a plurality of dies contained in a wafer, e.g. a silicon wafer, can be manufactured in parallel.

The dies may be singulated from the wafer after assembling the electrical components on the dies.

Preferably, the dies are singulated in a dicing before grinding (DBG) process. In a dicing before grinding process, first, the wafer is half-cut diced into dies from its front face side bearing the electrical components. After the dicing step the dies are still connected at their backside. In a second step the front side face is covered by a protection tape. In a further step the dies are fully singulated by grinding from the backside. After the dies are singulated, the protection tape can be removed.

Further passivation steps and metallization steps can be performed to all dies singulated from a single wafer in parallel and at the same time.

Therefore, a wafer level chip scale package process simplifies and accelerates the described manufacturing process.

### BRIEF DESCRIPTION OF THE DRAWINGS

In the following, the embodiments of the invention will be explained in more detail with reference to accompanied figures. Similar or apparently identical elements in the figures are marked with the same reference signs. The figures and the proportions in the figures are not scalable. The invention is not limited to the following embodiments. The figures show:

FIG. 1 shows schematically the manufacturing process of a TVS diode in a wafer level chip scale packaging process;

FIG. 2 shows a cross-sectional view of a first embodiment of a TVS diode; and

FIG. 3 shows a cross-sectional view of a second embodiment of a TVS diode.

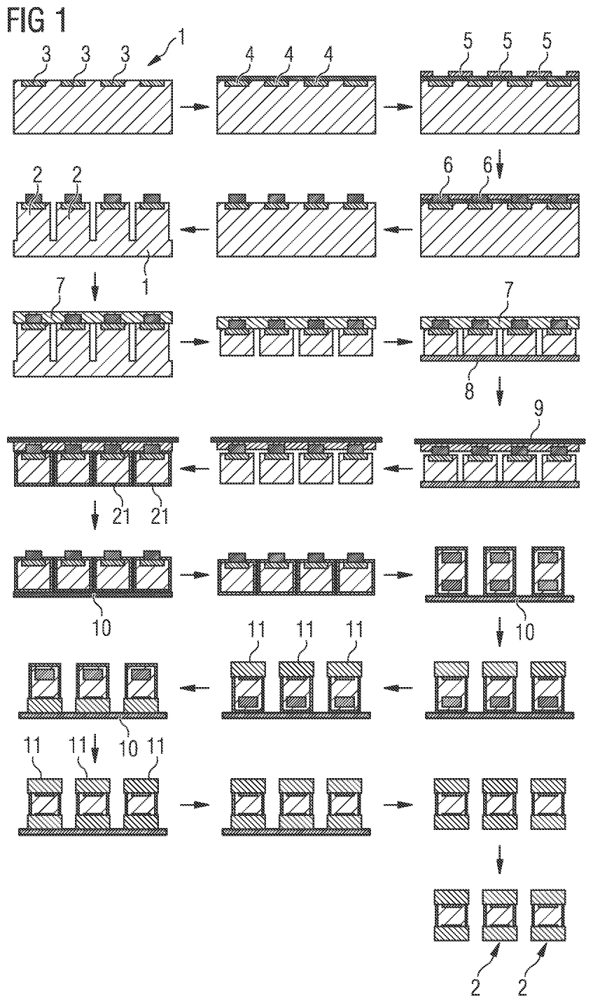

### DETAILED DESCRIPTION OF ILLUSTRATIVE EMBODIMENTS

In a first step of the so-called backend process a TVS diode semiconductor wafer 1 is provided. The wafer 1 is configured to be separated into several cuboid TVS diode dies 2. The wafer comprises a silicon based main body and electrical components 3 enclosed by the main body or applied to the frontside of the main body in a so-called frontend process. The TVS diode wafer 1 comprises several identical sections, which are later separated into the several cuboid TVS diode dies 2. The TVS diodes 2 are configured as semiconductor chips.

In a second step, a metal layer 4 is sputtered on the frontside of the wafer 1. The metal layer 4 comprises at least titan and/or copper. As the frontside, the side of the wafer 1 is defined to which the electrical components 3 are applied. Based on the sputtered metal layer 4, electrical contact areas for electrically contacting the TVS diodes to external contacts are designed.

In a third step, a mask layer 5 is applied to the frontside by photolithography. The mask layer 5 covers the whole surface of the frontside, except areas of the contact areas, to which contact pads 6 shall be applied in a following step.

In the following step, contact pads 6 are applied on the contact areas by electroplating. After performing electroplating, the mask layer 5 is removed by a stripping process.

By the steps described before, the TVS diode wafer 1 with contact pads 6 for external electrical contact is provided.

By the following procedure comprising another number of steps, the wafer 1 is singulated into semiconductor dies 2 and the dies are electrically passivated.

In a first step, the wafer 1 is divided into half-cut dies by a dicing saw from the frontside. The dicing is performed before grinding (dicing before grinding process, DBG). In an alternative process, the wafer 1 may be separated by another method.

After half-cut dicing is performed the frontside of the wafer 1 is covered by a back grinding tape 7 in a second step. The back grinding tape 7 protects the frontside of the wafer 1 and the applied electrical structures from damage during grinding. In a third step the wafer 1 is completely singulated into cuboid dies by grinding from the backside of the wafer 1, which is the side opposite to the frontside.

In an alternative process, cylindrical or different shaped dies 2 can be manufactured.

In a following step a transfer tape 8 is laminated to the grinded backside of the dies 2. The transfer tape 8 is used to transfer the dies 2 from the back grinding tape 7 to a film frame carrier 9. The film frame carrier 9 is a tape similar to the back grinding tape 7. However, due to a different adhesive layer the film frame carrier 9 does not cover the whole frontside of the singulated dies 2. In contrast to the back grinding tape 7, the film frame carrier 9 only covers contact regions of the contact pads 6 on the frontside of the dies 2. After the contact regions are covered by the film frame carrier 9, which also carries the dies 2, the transfer tape 8 is delaminated.

In a following process, all six sides of the singulated dies 2 are passivated in one step by an ALD (atomic layer deposition) process. Only the contact regions of the contact pads 6 covered by the film frame carrier 9 are not passivated during the ALD process. The advantage of the ALD process is that the process may be performed at low temperatures, below 80° C., preferably at room temperature.

After the passivation process is completed, the dies 2 are carried by a thermo release tape 10 and the film frame carrier 9 is delaminated. The sidewall passivated TVS diodes can be released from the thermo release tape 10 by heating to a predefined temperature.

The following steps describe the procedure of applying a metal cap 11 to the semiconductor dies 2. Each die 2 is configured as a six-side passivated cuboid TVS diode comprising two contact pads 6 providing contact regions on its frontside.

One contact pad 6 is arranged near a first side of the dies 2 on the frontside, the other contact pad is arranged near a second side of the dies 2 on the frontside. The first side and the second side are perpendicular to the frontside and opposite to each other.

To apply the metal caps 11, the first side of the dies 2 perpendicular to the frontside is loaded to a thermo release tape 10. Several dies 2 can be loaded to the thermo release tape 10 at the same time. For example, all dies 2 separated from a single wafer 1 can be loaded to the thermo release tape 10 at the same time.

Next, the semiconductor dies 2 carried by the thermo release tape 10 at their first side are dipped into a metal paste in order to apply a metal cap 11 to all dies 2 at the same time. By dipping the dies 2 into the metal paste in a first dipping step, metal caps 11 are applied at least to the second side and to sections of the sides of the die perpendicular to the second side comprising at least the contact pad near the second side. The metal caps 11 applied by dipping are dried for 10 to 60 minutes at an enhanced temperature.

In the following the dies 2 are transferred to another thermo release tape 10 applied to the second side of the dies 2 and the first side of the dies 2 is dipped in a second dipping step into a metal melt to metallize the first sides of the dies 2 opposite to the already metalized second sides. In an embodiment, the same thermo release tape 10 can be used in both dipping steps. After dipping the first sides in the metal melt, metal caps 11 are applied to at least the first side and to sections of the sides which are perpendicular to the first side comprising at least the contact pad near the first side, which is not covered by a metal cap 11 so far. The metal caps 11 applied by dipping are dried in a second drying step.

After both metal caps 11 are dried, the dies 2 are unloaded from the thermo release tape 10 by enhancing the temperature. The metal caps 11 can be hardened in the following by thermal treatment steps.

The metal caps 11 are electrically conductive and are in direct contact with the contact regions of the contact pads 6.

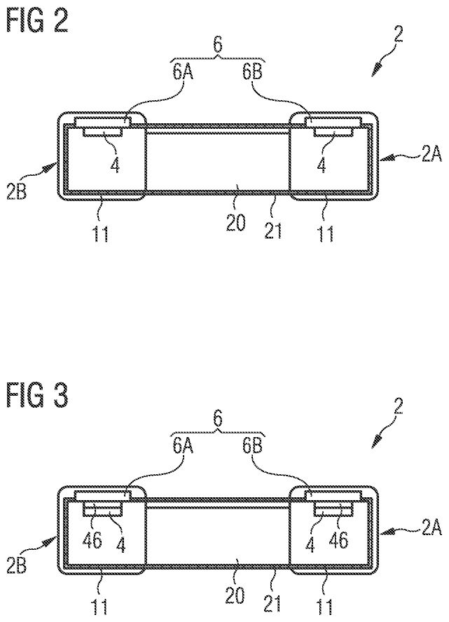

FIG. 2 shows a cuboid TVS diode die 2 manufactured by the above described process. The TVS diode die 2 has the following dimensions 300-1000 μm in length, 100-500 μm in width and 50-200 μm in height. The dimensions are preferably 600×300×150 μm or 400×200×100 μm (length×width×height).

Herein, the length is the dimension of the TVS diode die between the first and the second side. The width is the dimension of the edge between first side and frontside or between second side and frontside. The height is the dimension of the edge of the first or of the second side perpendicular to the frontside.

The TVS diode die 2 comprises a semiconductor base body 20, comprising preferably a silicon based material and electrical components embedded in the silicon based material. The silicon based material comprises at least silicon and further optional elements.

The base body 20 has a cuboid shape. Two contact pads 6 are applied to the frontside of the base body 20, electrically contacting the electrical components embedded in the base body 20. The contact pads 6 are applied near two opposite edges of the frontside. The first contact pad 6A is arranged near an edge between the frontside and the first side 2A and the second contact pad 6B is arranged near the edge between the frontside and the second side 2B.

The contact pads 6 comprise an electrically conductive metal like copper, nickel or gold. The dimensions of the contact pads 6 are for example up to 300 μm in the width direction and up to 100 μm in the length direction and about 5 to 10 μm, for example 6.5 μm, in the height direction. The distance between the two contact pads 6 in the length direction amounts for example 300 μm or preferably more than 400 μm.

The diode further has a passivation layer 21 comprising e.g. Al2O3 and/or TiO2. The passivation layer 21 has a thickness of 100 nm-200 nm. The passivation layer 21 is applied to all six sides of the cuboid diode except to contact regions of the contact pads 6. The contact regions can comprise the whole surfaces or sections of the surface of the contact pads 6.

Between the two contact pads 6 leakage current or parasitic capacitance effects can occur. Smaller contact pads 6 allow to increase the distance between the contact pads 6 and therefore decrease said parasitic effects.

The diode further comprises metal caps 11 applied to the first side and to the second side of the diode and to sections of the sides which are perpendicular to the first and to the second side adjacent to the first and to the second side.

The metal caps 11 have for example the shape of a cuboid cap.

A metal cap 11 comprises several layers consisting of different materials. For example, the metal cap 11 comprises three layers. The first layer is in direct contact with the contact pad and/or the passivation layer 21. The first layer may comprise a soft metallization mixture comprising Ag or Cu and a polymer.

The second layer comprises an electrically conductive metal like Cu or Ni.

The third layer is configured as an oxidation protection layer and comprises an appropriate metal like Au or Sn.

It should be mentioned that also by altering the passivation layer (e.g. material and thickness) and by altering the type of Si substrate (e.g. selection of a non epi-material or a low-doped material) the electrical performance of the TVS-diode (e.g. capacitance) can be tuned. These tunings together with an appropriate contact pad/metal cap design enable the disclosed diode to address various applications requiring different electrical specifications (e.g. different capacitance).

In the embodiment shown in FIG. 3 additional interlayers 46 is positioned between the metal layer 4 and the contact pad 6. The interlayers 46 connect the metal layers 4 electrically and mechanically with the contact pads 6. The interlayers 46 are firmly bonded to the adjacent metal layer 4 and contact pad 6.

By the interlayer 46 the connection between the metal layer 4 and the contact pad 6 can be improved and enforced.

The interlayer 46 comprises an electrically conductive material, for example a conductive metal.

The material of the interlayer 46 may be different than the material of the metal layer 4 and the contact pad 6.

Besides, the embodiment in FIG. 3 is similar or identical to the embodiment shown in FIG. 2.

### REFERENCE SIGNS

1 Wafer
2 TVS diode die
2A First side of the diode
2B Second side of the diode
3 electrical components
4 metal layer
46 interlayer
5 mask layer
6 contact pads
6A first contact pad
6B second contact pad
7 back grinding tape
8 transfer tape
9 film frame carrier
10 thermo release tape
11 metal cap
20 base body
21 passivation layer

1.-15. (canceled)

16. A semiconductor die comprising:
a base body comprising:
a semiconductor material; and
a surface with two contact areas having contact pads at which the semiconductor die is electrically contactable and two metal caps arranged directly at the contact pads.

17. The semiconductor die according to claim 16, further comprising two interlayers connecting the contact areas with the contact pads.

18. The semiconductor die according to claim 16,
wherein the surface with the two contact areas is a frontside surface,
wherein a first contact area of the two contact areas is arranged near a first side of the die and a second contact area of the two contact areas is arranged near a second side of the die, the second side being arranged opposite to the first side, wherein the first side and the second side are perpendicular to the frontside surface, and
wherein the metal caps are contiguously arranged at the first side and the second side and respectively to each four sides adjacent to the first or second side of the semiconductor die.

19. The semiconductor die according to claim 16, wherein the contact areas are structural elements comprising conductive metals.

20. The semiconductor die according to claim 16, further comprising a passivation layer configured to electrical passivate the surface of the semiconductor die, wherein areas free of passivation layer are provided allowing for external access to each contact pad.

21. A method for manufacturing a semiconductor die, the method comprising:
providing the semiconductor die including a base body comprising a semiconductor material and a surface with two contact areas having contact pads at which the semiconductor die is electrically contactable;
applying a passivation layer for electrical passivation to the surface of the semiconductor die thereby providing areas free of passivation allowing external access to each contact pad; and
metallizing parts of the surface of the semiconductor die with metal caps, the metal caps directly contacting the contact pads.

22. The method according to claim 21, wherein the method is performed in the recited order.

23. The method according to claim 21, further comprising:
loading the semiconductor die on a first side to a first metallization tape;
metallizing a contiguous area of the semiconductor die not covered by the first metallization tape including at least one contact pad;
loading the semiconductor die on a second side to a second metallization tape; and
metallizing a contiguous area of the semiconductor die not covered by the second metallization tape including at least one contact pad.

24. The method according to claim 23, wherein the first or second metallization tape is a polymer tape with an adhesive layer.

25. The method according to claim 23, further comprising:
releasing the semiconductor die from the first metallization tape after first metallizing and optionally first hardening; and
releasing the semiconductor die from the second metallization tape after second metallizing and optionally second hardening.

26. The method according to claim 21, further comprising:
hardening a metal cap on a second side of the semiconductor die after first metallizing; and
hardening a metal cap on a first side of the semiconductor die after second metallizing.

27. The method according to claim 21,
wherein the surface with the two contact areas is a frontside surface,
wherein a first contact area of the two contact areas is arranged near a first side of the semiconductor die and a second contact area of the two contact areas is arranged near a second side of the semiconductor die, the second side being arranged opposite to the first side,
wherein the first side and the second side are perpendicular to the frontside surface, and
wherein the metal caps are contiguously applied to the first side and the second side and respectively to each four sides adjacent to the first or second side of the semiconductor die.

28. The method according to claim 21, further comprising externally contacting the semiconductor die via the metal caps.

29. The method according to claim 21, further comprising externally contacting the semiconductor die via soldering the metal caps to a printed circuit board.

30. The method according to claim 21, wherein the metal caps are directly applied to the passivation layer.

31. The method according to claim 21, wherein the metal caps are applied by a dipping process.

32. The method according to claim 21, wherein the metal caps comprise two or three different stacked layers applied by two or three metalizing steps.

33. The method according to claim 21, wherein the metal caps comprise metals or a mixture of metals which is different from that of the contact pads.

34. The method according to claim 21, wherein the passivation layer is applied by an atomic layer deposition process.

35. The method according to claim 34, wherein the atomic layer deposition process is performed at a temperature lower than 80° ° C.

36. The method according to claim 21, wherein several semiconductor dies are manufactured in parallel by a wafer level chip scale package process.
